(19) United States
(12) Patent Application Publication
(10) Pub. No.: US 2026/0204315 A1
(43) Pub. Date: Jul. 16, 2026

(54) MEMORY PERFORMING COMPUTING OPERATION AND OPERATION METHOD OF MEMORY SYSTEM

(71) Applicant: SK hynix Inc., Gyeonggi-do (KR)

(72) Inventors: Dong Hwan JIN, Gyeonggi-do (KR); Seok Joon KANG, Gyeonggi-do (KR); Jun Ho CHEON, Gyeonggi-do (KR); Sang Hoon JEONG, Gyeonggi-do (KR); Chang Won JEONG, Gyeonggi-do (KR)

(21) Appl. No.: 19/209,703

(22) Filed: May 15, 2025

(30) Foreign Application Priority Data
Jan. 15, 2025 (KR) 10-2025-0006220

(51) Int. Cl. G11C 13/00; G11C 7/16; G11C 11/54

(52) U.S. Cl. CPC G11C 13/0069; G11C 7/16; G11C 11/54

(57) ABSTRACT

A memory includes a plurality of bit lines, a source line coupled to a source line driver; and a plurality of memory cells connected between the source line and each of the plurality of bit lines. The plurality of memory cells are programmed with adjustment resistance values adjusted from target programming resistance values.

### CROSS-REFERENCE TO RELATED APPLICATION

This application claims priority under 35 U.S.C. § 119(a) to Korean Patent Application No. 10-2025-0006220 filed on Jan. 15, 2025, which is incorporated herein by reference in its entirety.

### BACKGROUND

### 1. Technical Field

Embodiments of the present disclosure relate to a memory design, and more particularly, to a memory performing a computing operation, and an operation method of a memory system including the memory.

### 2. Related Art

Electronic devices include many electronic components, and among the electronic devices, a computer system includes many electronic components made of semiconductors. Among the semiconductor constituting the computer system, a host device such as a processor or memory controller performs data communication with a memory. The memory stores data by including a large number of memory cells arranged in a plurality of rows and a plurality of columns.

Recently, technologies utilizing the memory for computing operations are being developed to improve the performance of data processing. When the memory directly computes internally without transmitting data to the processor, delay due to data movement can be reduced and energy efficiency can be increased.

### SUMMARY

In an embodiment of the present disclosure, a memory may include a plurality of bit lines; a plurality of memory cells each having one end connected to each of the plurality of bit lines; and a source line connected to the other end of each of the plurality of memory cells. The plurality of memory cells are programmed with adjustment resistance values adjusted from target programming resistance values.

The adjustment resistance values may be generated by applying different reduction rates to the target programming resistance values, and a reduction rate may be greater as a corresponding memory cell, among the plurality of memory cells, is farther away from the source line driver.

In an embodiment of the present disclosure, an operating method of a memory system may include obtaining target programming resistance values corresponding to weight values of an artificial neural network; generating adjustment resistance values by applying different reduction rates to the target programming resistance values; and programming the adjustment resistance values into a plurality of memory cells connected between a source line and a plurality of bit lines.

A reduction rate may be greater as a corresponding memory cell, among the plurality of memory cells, is farther away from a source line driver driving the source line.

### BRIEF DESCRIPTION OF THE DRAWINGS

FIG. 1 illustrates an equation indicating a multiply-and-accumulation (MAC) operation being the most important operation of deep learning.

FIG. 2 is a diagram illustrating a configuration of a memory in accordance with an embodiment of the present disclosure.

FIG. 3 is a diagram for describing an IR drop occurring in a source line in FIG. 2 during a MAC operation.

FIG. 4 is a flowchart illustrating an operation of a memory system in accordance with an embodiment of the present disclosure.

### DETAILED DESCRIPTION

Various embodiments of the present disclosure are directed to providing a technology of increasing the accuracy of a computing operation of a memory by compensating for an IR drop occurring in a cell array of the memory.

Embodiments of the present disclosure can increase the accuracy of a computing operation of a memory by compensating for an IR drop occurring in a cell array of the memory.

Hereafter, embodiments in accordance with the technical scope of the present disclosure are described with reference to the accompanying drawings.

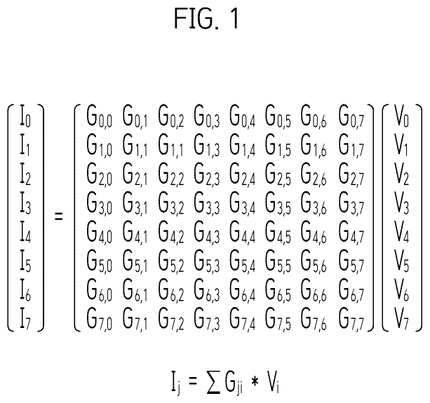

FIG. 1 illustrates an equation indicating a multiply-and-accumulation (MAC) operation being the most important operation of deep learning.

In an embodiment, an output I of the MAC operation is defined as the sum of the products of a weight G and an input V. In the MAC operation using a memory, the symbol of the weight is indicated as G because the weight is expressed as the conductance of a memory cell, the symbol of the input is indicated as V because the input is expressed as voltage, and the symbol of the output is indicated as I because the output is expressed as current.

In the following embodiment of the memory, because the size of a cell array is 8×8, the number of inputs V is 8 (V₀ to V₇), the number of outputs I is 8 (I₀ to I₇), and the number of weights G is 64 G_{0,0} to G_{0,7}, G_{1,0} to G_{1,7}, G_{2,0} to G_{2,7}, G_{3,0} to G_{3,7}, G_{4,0} to G_{4,7}, G_{5,0} to G_{5,7}, G_{6,0} to G_{6,7}, and G_{7,0} to G_{7,7}.

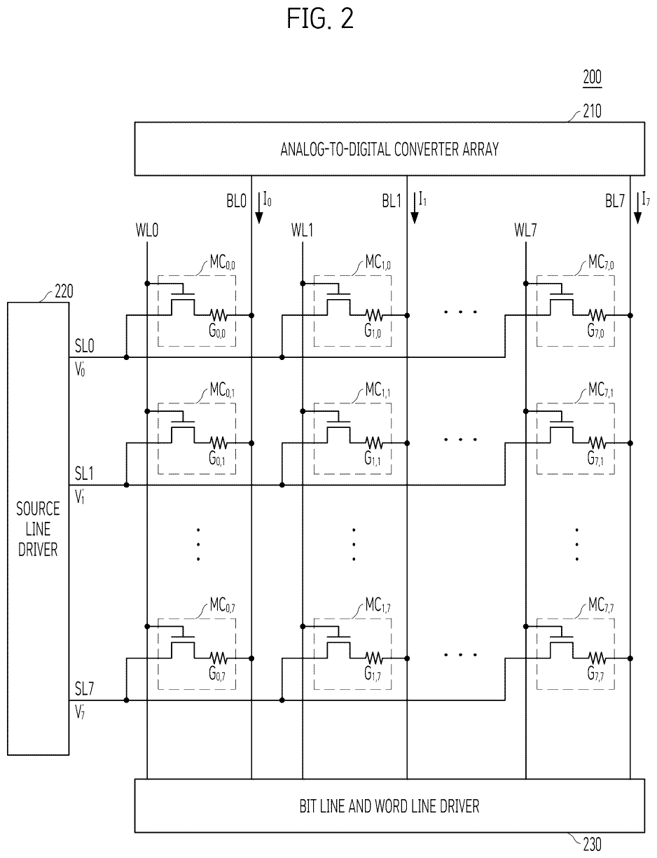

FIG. 2 is a diagram illustrating a configuration of a memory 200 in accordance with an embodiment of the present disclosure.

Referring to FIG. 2, the memory 200 may include word lines WL0 to WL7, bit lines BL0 to BL7, source lines SL0 to SL7, memory cells MC_{0,0} to MC_{0,7}, MC_{1,0} to MC_{1,7}, MC_{2,0} to MC_{2,7}, MC_{3,0} to MC_{3,7}, MC_{4,0} to MC_{4,7}, MC_{5,0} to MC_{5,7}, MC_{6,0} to MC_{6,7}, and MC_{7,0} to MC_{7,7}, an analog-to-digital converter array 210, a source line driver 220, a bit line and word line driver 230.

In an embodiment, the word lines WL0 to WL7 and bit lines BL0 to BL7 alternately extend in a first direction. One word line WL and one bit line BL adjacent to each other form a pair. The source lines SL0 to SL7 extend in a second direction intersecting the first direction. The number of word lines WL0 to WL7, the number of bit lines BL0 to BL7, and the number of source lines SL0 to SL7 illustrated in FIG. 2 are merely an example and are changed according to an embodiment.

In an embodiment, the memory cells MC_{0,0} to MC_{0,7}, MC_{1,0} to MC_{1,7}, MC_{2,0} to MC_{2,7}, MC_{3,0} to MC_{3,7}, MC_{4,0} to MC_{4,7}, MC_{5,0} to MC_{5,7}, MC_{6,0} to MC_{6,7}, and MC_{7,0} to MC_{7,7} are connected to one of the bit lines BL0 to BL7 and one of the source lines SL0 to SL7, and are connected to the word lines WL having the same number as the bit lines BL to which they are connected. In the numbers of the memory cells MC_{0,0} to MC_{0,7}, MC_{1,0} to MC_{1,7}, MC_{2,0} to MC_{2,7}, MC_{3,0} to MC_{3,7}, MC_{4,0} to MC_{4,7}, MC_{5,0} to MC_{5,7}, MC_{6,0} to MC_{6,7}, and MC_{7,0} to MC_{7,7}, the preceding numbers indicate the numbers of the bit lines BL and word lines WL to which they are connected, and the following numbers indicate the numbers of the source lines SL to which they are connected. Each of the memory cells MC_{0,0} to MC_{0,7}, MC_{1,0} to MC_{1,7}, MC_{2,0} to MC_{2,7}, MC_{3,0} to MC_{3,7}, MC_{4,0} to MC_{4,7}, MC_{5,0} to MC_{5,7}, MC_{6,0} to MC_{6,7}, and MC_{7,0} to MC_{7,7} includes a variable resistor G having a programmed resistance value and a transistor. According to an embodiment, the memory cell is implemented as a phase change random access memory (PRAM) cell, a resistance random access memory (RRAM) cell, a magnetic random access memory (MRAM) cell, a ferroelectric random access memory (FRAM) cell, or the like, but the embodiment is not limited thereto. In addition, according to an embodiment, the variable resistor includes a phase-change material, a perovskite compound, a transition metal oxide, a magnetic material, a ferromagnetic material, or an antiferromagnetic material, but the embodiment is not limited thereto.

In an embodiment, the analog-to-digital converter array 210 may generate result codes MAC_0<0:m> to MAC_7<0:m> by analog-to-digital converting currents I₀ to I₇ of the bit lines BL0 to BL7. The result codes MAC_0<0:m> to MAC_7<0:m> are digital codes corresponding to I₀ to I₇ of FIG. 1. The analog-to-digital converter array 210 may apply a voltage (for example, 0.1 V) for an analog-to-digital conversion operation to the bit lines BL0 to BL7 during an analog-to-digital conversion operation.

In an embodiment, the source line driver 220 may apply voltages V₀′ to V₇′ to the source lines SL0 to SL7. The bit line and word line driver 230 may apply voltages to the bit lines BL0 to BL7 and the word lines WL0 to WL7. The resistance values of the variable resistors G_{0,0} to G_{0,7}, G_{1,0} to G_{1,7}, G_{2,0} to G_{2,7}, G_{3,0} to G_{3,7}, G_{4,0} to G_{4,7}, G_{5,0} to G_{5,7}, G_{6,0} to G_{6,7}, and G_{7,0} to G_{7,7} of the memory cells MC_{0,0} to MC_{0,7}, MC_{1,0} to MC_{1,7}, MC_{2,0} to MC_{2,7}, MC_{3,0} to MC_{3,7}, MC_{4,0} to MC_{4,7}, MC_{5,0} to MC_{5,7}, MC_{6,0} to MC_{6,7}, and MC_{7,0} to MC_{7,7} are programmed by controlling voltage levels applied to both ends of the memory cells MC_{0,0} to MC_{0,7}, MC_{1,0} to MC_{1,7}, MC_{2,0} to MC_{2,7}, MC_{3,0} to MC_{3,7}, MC_{4,0} to MC_{4,7}, MC_{5,0} to MC_{5,7}, MC_{6,0} to MC_{6,7}, and MC_{7,0} to MC_{7,7} through the control of voltage levels applied to the source lines SL0 to SL7 and the bit lines BL0 to BL7, and by adjusting the degree to which the transistors of the memory cells MC_{0,0} to MC_{0,7}, MC_{1,0} to MC_{1,7}, MC_{2,0} to MC_{2,7}, MC_{3,0} to MC_{3,7}, MC_{4,0} to MC_{4,7}, MC_{5,0} to MC_{5,7}, MC_{6,0} to MC_{6,7}, and MC_{7,0} to MC_{7,7} are turned on through the control of the word lines WL0 to WL7. For the MAC operation, the variable resistors G_{0,0} to G_{0,7}, G_{1,0} to G_{1,7}, G_{2,0} to G_{2,7}, G_{3,0} to G_{3,7}, G_{4,0} to G_{4,7}, G_{5,0} to G_{5,7}, G_{6,0} to G_{6,7}, and G_{7,0} to G_{7,7} of the memory cells MC_{0,0} to MC_{0,7}, MC_{1,0} to MC_{1,7}, MC_{2,0} to MC_{2,7}, MC_{3,0} to MC_{3,7}, MC_{4,0} to MC_{4,7}, MC_{5,0} to MC_{5,7}, MC_{6,0} to MC_{6,7}, and MC_{7,0} to MC_{7,7} are programmed to have conductance values identical to the weight values of FIG. 1.

The process in which a MAC operation is performed in the memory 200 is described below. The process in which the word line WL0 is activated, the transistors of the memory cells MC_{0,0} to MC_{0,7} are turned on, and I₀ in FIG. 1 is operated is described below. Simultaneously with the operation of I₀, I₁ to I₇ are also operated in the same manner.

In an embodiment, the word line WL0 is activated and the transistors of the memory cells MC_{0,0} to MC_{0,7} are turned on. Accordingly, current paths are formed between the bit line BL0 and the source lines SL0 to SL7 through the memory cells MC_{0,0} to MC_{0,7}. Such a case, a voltage V_{BL} of 0.1 V is applied to the bit line BL0 by the analog-to-digital converter array 210.

In an embodiment, the input voltages V₀′ to V₇′ are applied to the source lines SL0 to SL7. A current of G_{0,0}*(0.1−V₀′) is sunk from the bit line BL0 to the source line SL0, and a current of G_{0,1}*(0.1−V₁′) is sunk from the bit line BL0 to the source line SL1. That is, a current of G_{0,x}*(0.1−Vₓ′) is sunk from the bit line BL0 to the source line SLx. Here, G_{0,x} is the conductance of the variable resistance of the memory cell MC_{0,x}, and Vₓ′ and Vₓ in FIG. 1 have a relationship of Vₓ′=0.1−Vₓ. As a result, a current of

$${\sum }_{x = 0}^{7} {G}_{0 , x} * {V}_{x}$$

flows from the bit line BL0 to the source lines SL0 to SL7, which is the same as I₀ in FIG. 1. That is, I₀ of FIG. 2 and I₀ in FIG. 1 are the same. The analog-to-digital converter array 210 generates the result code MAC_0<0:m> corresponding to the value of I₀ in FIG. 1 by analog-to-digital converting the current I₀. Similarly, the analog-to-digital converter array 210 generates the result codes MAC_1<0:m> to MAC_7<0:m> corresponding to the values of I₁ to I₇ in FIG. 1 by analog-to-digital converting the currents I₁ to I₇.

In an embodiment, to improve the accuracy of the MAC operation, the voltages of the source lines SL0 to SL7 need to be maintained constant. During the MAC operation, the input voltages V₀′ to V₇′ of 0 V or 0.1 V are applied to the source lines SL0 to SL7. Among the source lines SL0 to SL7, no current flows to a source line whose value of the input voltage V′ is 0.1 V, but among the source lines SL0 to SL7, current flows to a source line whose value of the input voltage V′ is 0 V, causing an IR drop due to the resistance of the source line itself, and thus, the voltage level of the source line is not maintained constant. For example, when the input voltage V₀′ of the source line SL0 is 0.1 V, because no current flows to the source line SL0, no IR drop occurs. However, when the input voltage V₀′ of the source line SL0 is 0 V, current flows to the source line SL0, so that voltage levels on the left and right sides of the source line SL0 are changed.

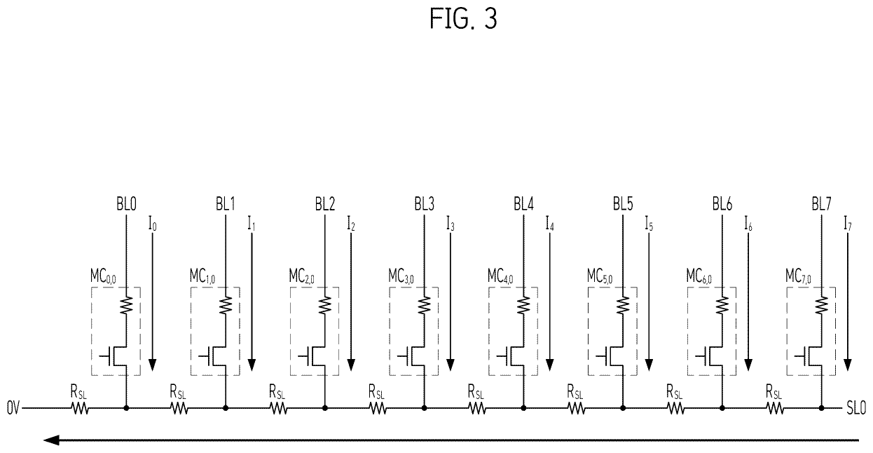

FIG. 3 is a diagram for describing an IR drop occurring in the source line SL0 in FIG. 2 during a MAC operation.

Referring to FIG. 3, it can be confirmed that the input voltage V₀′ of OV is applied to the left side of the source line SL0 by the source line driver 220. R_{SL} represents the partial resistance value of the source line SL0. For example, the resistance between a contact point of the source line SL0 and the memory cell MC_{0,0} and a contact point of the source line SL0 and the memory cell MC_{1,0} is represented as R_{SL}, and the resistance between a contact point of the source line SL0 and the memory cell MC_{1,0} and a contact point of the source line SL0 and the memory cell MC_{2,0} is represented as R_{SL}.

In an embodiment, when the resistance of the source line SL0 is 0, the entire source line SL0 has a voltage level of 0 V. That is, V_{SL}<0> to V_{SL}<7> are all 0 V. However, because it is not possible for the resistance of the source line SL0 to be 0, the voltage level of the source line SL0 varies depending on the position. That is, V_{SL}<0> to V_{SL}<7> have a voltage level other than 0 V.

In an embodiment, I_{CELL}<0> to I_{CELL}<7> represent currents flowing from the memory cells MC_{0,0}, MC_{1,0}, MC_{2,0}, MC_{3,0}, MC_{4,0}, MC_{5,0}, MC_{6,0}, and MC_{7,0} to the source line SL0. Because the current flows from right to left on the source line SL0, the current amount of the source line SL0 increases toward the left. The values of the voltages V_{SL}<0> to V_{SL}<7> are calculated as follows by using the current flowing through the source line SL0 and the IR drop due to the resistance R_{SL} of the source line SL.

$${V}_{SL} < 0 >= ( {I}_{CELL} < 0 > + {I}_{CELL} < 1 > + {I}_{CELL} < 2 > + {I}_{CELL} < 3 > + {I}_{CELL} < 4 > + {I}_{CELL} < 5 > + {I}_{CELL} < 6 > + {I}_{CELL} < 7 > ) * {R}_{SL}$$

$${V}_{SL} < 1 >= {V}_{SL} < 0 > + ( {I}_{CELL} < 1 > + {I}_{CELL} < 2 > + {I}_{CELL} < 3 > + {I}_{CELL} < 4 > + {I}_{CELL} < 5 > + {I}_{CELL} < 6 > + {I}_{CELL} < 7 > ) * {R}_{SL}$$

$${V}_{SL} < 2 >= {V}_{SL} < 1 > + ( {I}_{CELL} < 2 > + {I}_{CELL} < 3 > + {I}_{CELL} < 4 > + {I}_{CELL} < 5 > + {I}_{CELL} < 6 > + {I}_{CELL} < 7 > ) * {R}_{SL}$$

$${V}_{SL} < 3 >= {V}_{SL} < 2 > + ( {I}_{CELL} < 3 > + {I}_{CELL} < 4 > + {I}_{CELL} < 5 > + {I}_{CELL} < 6 > + {I}_{CELL} < 7 > ) * {R}_{SL}$$

$${V}_{SL} < 4 >= {V}_{SL} < 3 > + ( {I}_{CELL} < 4 > + {I}_{CELL} < 5 > + {I}_{CELL} < 6 > + {I}_{CELL} < 7 > ) * {R}_{SL}$$

$${V}_{SL} < 5 >= {V}_{SL} < 4 > + {I}_{CELL} < 5 > + {I}_{CELL} < 6 > + {I}_{CELL} < 7 > ) * {R}_{SL}$$

$${V}_{SL} < 6 >= {V}_{SL} < 5 > + ( {I}_{CELL} < 6 > + {I}_{CELL} < 7 > ) * {R}_{SL}$$

$${V}_{SL} < 7 >= {V}_{SL} < 6 > + ( {I}_{CELL} < 7 > ) * {R}_{SL}$$

The voltage level of V_{SL}<k> is more generally organized as the following Equation 1.

$${V}_{SL} < k >= ( {R}_{SL} \times {\sum }_{i = k}^{N} {I}_{CELLt} < k > ) + {V}_{SL} < K - 1 > \qquad Equation 1$$

In Equation 1 above, 0≤k≤N and V_{SL}<−1> is 0.

In Equation 1 above, the cell current of the memory cell MC_{k,0} is expressed as I_{CELLt}<k>, which represents the target current amount of a corresponding memory cell, that is, an ideal current amount.

When the voltage level of the bit lines BL0 to BL7 is V_{BL}, the resistance value R_{CELLc}<k> of the memory cells MC_{0,0} to MC_{0,7}, MC_{1,0} to MC_{1,7}, MC_{2,0} to MC_{2,7}, MC_{3,0} to MC_{3,7}, MC_{4,0} to MC_{4,7}, MC_{5,0} to MC_{5,7}, MC_{6,0} to MC_{6,7}, and MC_{7,0} to MC_{7,7} is expressed as the following Equation 2.

$${R}_{CELLc} < k >= \frac{{V}_{BL} - {V}_{SL} < k >}{{I}_{CELLt} < k >} \qquad Equation 2$$

In Equation 2 above, R_{CELLc}<k> represents an adjustment resistance value of the memory cell MC_{k,0}, which means a resistance value for allowing current having the target current amount I_{CELLt}<k> to flow through the memory cell MC_{k,0} even though the voltage level of the source line SL is not maintained constant due to the IR drop of the source line SL.

Because the target current amount I_{CELLt}<k> means the amount of current flowing through the memory cell MC_{k,0} when there is no IR drop on the source line SL0, the target current amount I_{CELLt}<k> is expressed by the following Equation 3 by using the target programming resistance value R_{CELL}<k> being a resistance value in an ideal situation.

$${I}_{CELLt} < k >= \frac{{V}_{BL}}{{R}_{CELL} < k >} = {G}_{k , 0} \times {V}_{BL} \qquad Equation 3$$

When the adjustment resistance value R_{CELLc}<k> is expressed as adjustment conductance G_{k,0}′ and Equation 3 above is substituted into Equation 2 above and organized, the following Equation 4 is derived.

$$\frac{1}{{R}_{CELLc} < k >} = {{G}_{k , 0}}^{′} = \frac{{V}_{BL}}{{V}_{BL} - {V}_{SL} < k >} {G}_{k , c} \qquad Equation 4$$

Referring to Equation 4, it can be confirmed that the adjustment conductance G_{k,0}′ has a value that is increased compared to target programming conductance (conductance in an ideal case) G_{k,0}. In addition, because the value of V_{SL}<k> increases as the value of k increases, the increase rate of the adjustment conductance G_{k,0}′ compared to the target programming conductance G_{k,0} is greater as the value of k increases (memory cell farther away from the source line driver).

Because the adjustment resistance value R_{CELLc}<k> has an inverse relationship with the adjustment conductance G_{k,0}′, it can be seen that the adjustment resistance value R_{CELLc}<k> has a value that is decreased compared to the target programming resistance value R_{CELL}<k> and a reduction rate is greater as the value of k increases, that is, the farther the memory cell is from the source line driver 220.

By programming the adjustment conductance G_{0,0}′, G_{1,0}′, G_{2,0}′, G_{3,0}′, G_{4,0}′, G_{5,0}′, G_{6,0}′, and G_{7,0}′ into the memory cells MC_{0,0}, MC_{1,0}, MC_{2,0}, MC_{3,0}, MC_{4,0}, MC_{5,0}, MC_{6,0}, and MC_{7,0} instead of the target programming conductance G_{0,0}, G_{1,0}, G_{2,0}, G_{3,0}, G_{4,0}, G_{5,0}, G_{6,0}, and G_{7,0}, it is possible to compensate for an IR drop occurring in the source line SL0. That is, by programming the adjustment resistance value R_{CELLc}<k> into the memory cells MC_{0,0}, MC_{1,0}, MC_{2,0}, MC_{3,0}, MC_{4,0}, MC_{5,0}, MC_{6,0}, and MC_{7,0} instead of the target programming resistance value R_{CELL}<K>, it is possible to compensate for the IR drop occurring in the source line SL0. Although the memory cells MC_{0,0}, MC_{1,0}, MC_{2,0}, MC_{3,0}, MC_{4,0}, MC_{5,0}, MC_{6,0}, and MC_{7,0} are described as an example, an IR drop occurring in the source lines SL1 to SL7 can be compensated for by programming the adjustment conductance G_{0,1}′ to G_{7,1}′, G_{0,2}′ to G_{7,2}′, G_{0,3}′ to G_{7,3}′, G_{0,4}′ to G_{7,4}′, G_{0,5}′ to G_{7,5}′, G_{0,6}′ to G_{7,6}′, and G_{0,7}′ to G_{7,7}′ into the remaining memory cells MC_{0,1} to MC_{7,1}, MC_{0,2} to MC_{7,2}, MC_{0,3} to MC_{7,3}, MC_{0,4} to MC_{7,4}, MC_{0,5} to MC_{7,5}, MC_{0,6} to MC_{7,6}, and MC_{0,7} to MC_{7,7} as well.

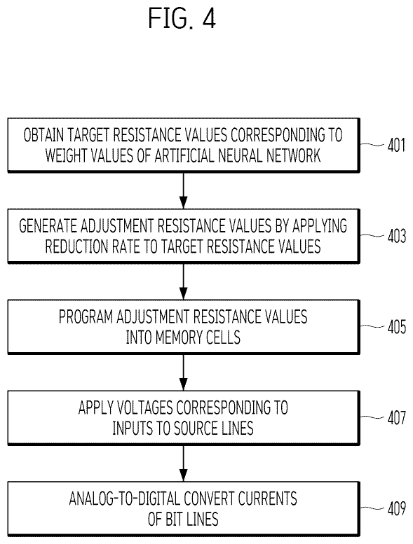

FIG. 4 is a flowchart illustrating an operation of a memory system in accordance with an embodiment of the present disclosure. The memory system refers to a system including the memory 200, and is configured as a processor including the memory 200 and a memory controller that controls the memory 200. In some cases, the memory controller may not be included in the processor but may be provided separately.

First, target programming resistance values corresponding to weight values of an artificial neural network are obtained (401). The weight values vary depending on which artificial neural network trained in what manner is used, and this process (401) is performed by the processor.

Adjustment resistance values to which reduction rates are applied to the target programming resistance values are generated (403). In the same manner as described with reference to Equations 1 to 4 above, the adjustment resistance values are calculated from the target programming resistance values. This process (403) is also performed by the processor or the memory controller, or an adjustment resistance value generation circuit is provided inside the memory 200 and this process (403) is performed by the adjustment resistance value generation circuit.

The adjustment resistance values are programmed into the memory cells of the memory 200 (405). Accordingly, an artificial neural network is constructed into the memory 200. Because the adjustment resistance values are programmed into the memory cells, the voltage level imbalance of the source lines SL0 to SL7 due to the IR drop on the source lines SL0 to SL7 are compensated.

The voltages V₀′ to V₇′ corresponding to the inputs V₀ to V₇ in FIG. 1 are applied to the source lines SL0 to SL7 of the memory 200 (407). Subsequently, the result codes MAC_0<0:m> to MAC_7<0:m> are generated by analog-to-digital converting the currents I₀ to I₇ of the bit lines BL0 to BL7 (409). The result codes MAC_0<0:m> to MAC_7<0:m> serve as MAC operation results.

The processes 407 and 409 are performed a plurality of times while changing the voltages V₀′ to V₇′, and in this way, various MAC operations are performed in the memory 200.

Although embodiments according to the technical idea of the present disclosure have been described above with reference to the accompanying drawings, this is only for describing the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical scope of the present disclosure. It should be construed that these substitutions, modifications, and changes belong to the scope of the present disclosure. Furthermore, the embodiments may be combined to form additional embodiments.

What is claimed is:

1. A memory comprising:
a plurality of bit lines;
a source line coupled to a source line driver; and
a plurality of memory cells connected between the source line and each of the plurality of bit lines,
wherein the plurality of memory cells are programmed with adjustment resistance values adjusted from target programming resistance values.

2. The memory of claim 1, wherein the adjustment resistance values are generated by applying different reduction rates to the target programming resistance values, and
a reduction rate is greater as a corresponding memory cell, among the plurality of memory cells, is farther away from the source line driver.

3. The memory of claim 2, wherein the target programming resistance values correspond to weight values of an artificial neural network.

4. The memory of claim 3, wherein a voltage level of the source line corresponds to an input value of the artificial neural network.

5. The memory of claim 2, further comprising an analog-to-digital converter array coupled to the plurality of bit lines and configured to simultaneously convert currents flowing from the plurality of bit lines to the source line into digital codes.

6. The memory of claim 2, wherein, when the plurality of memory cells include 0^{th} to N^{th} memory cells of which memory cells with lower numbers are closer to the source line driver,
an adjustment resistance value R_{CELLc}<K> of a k^{th} memory cell is determined by a following equation:
$${R}_{CELLc} < k >= \frac{{V}_{BL} - {V}_{SL} < k >}{{I}_{CELLt} < k >} ,$$
wherein V_{BL} denotes a voltage level of a corresponding bit line, I_{CELLt}<k> denotes a target current value of the k^{th} memory cell, and V_{SL}<k> denotes a voltage level of the source line at a connection terminal of the k^{th} memory cell and is determined by a following
$${V}_{SL} < k >= ( {R}_{SL} \times {\sum }_{i = k}^{N} {I}_{CELLt} < k > ) + {V}_{SL} < K - 1 >$$
equation:
wherein R_{SL} denotes a partial resistance value of the source line, 0≤k≤N, and V_{SL}<−1> is 0.

7. The memory of claim 2, further comprising an adjustment resistance value generation circuit configured to generate the adjustment resistance values by using the target programming resistance values.

8. An operating method of a memory system, the operating method comprising:
obtaining target programming resistance values corresponding to weight values of an artificial neural network;
generating adjustment resistance values by applying different reduction rates to the target programming resistance values; and
programming the adjustment resistance values into a plurality of memory cells connected between a source line and a plurality of bit lines.

9. The operating method of claim 8, wherein a reduction rate is greater as a corresponding memory cell, among the plurality of memory cells, is farther away from a source line driver driving the source line.

10. The operating method of claim 9, further comprising applying, to the source line, a voltage having a level corresponding to an input value of the artificial neural network.

11. The operating method of claim 9, further comprising simultaneously converting currents flowing from the plurality of bit lines to the source line into digital codes.

12. The operating method of claim 9,
wherein the plurality of memory cells include 0^{th} to N^{th} memory cells of which memory cells with lower numbers are closer to the source line driver, and
wherein an adjustment resistance value R_{CELLc}<K> of a k^{th} memory cell is determined by a following equation:
$${R}_{CELLc} < k >= \frac{{V}_{BL} - {V}_{SL} < k >}{{I}_{CELLt} < k >} ,$$
wherein V_{BL} denotes a voltage level of a corresponding bit line, I_{CELLt}<k> denotes a target current value of the k^{th} memory cell, and V_{SL}<k> denotes a voltage level of the source line at a connection terminal of the k^{th} memory cell and is determined by a following equation:
$${V}_{SL} < k >= ( {R}_{SL} \times {\sum }_{i = k}^{N} {I}_{CELLt} < k > ) + {V}_{SL} < K - 1 >$$
and wherein R_{SL} denotes a partial resistance value of the source line, 0≤k≤N, and V_{SL}<−1> is 0.
